(19) United States
(12) Patent Application Publication
(10) Pub. No.: US 2026/0372214 A1
(43) Pub. Date: Nov. 19, 2026

(54) MANUFACTURING METHOD OF SEMICONDUCTOR PACKAGE

(71) Applicant: Taiwan Semiconductor Manufacturing Company, Ltd., Hsinchu (TW)

(72) Inventors: Chao-Wei Chiu, Hsinchu City (TW); Ching-Hua Hsieh, Hsinchu (TW); Hsiu-Jen Lin, Hsinchu County (TW); Hao-Jan Pei, Hsinchu (TW); Chia-Shen Cheng, Hsinchu County (TW); Hsuan-Ting Kuo, Taichung City (TW)

(73) Assignee: Taiwan Semiconductor Manufacturing Company, Ltd., Hsinchu (TW)

(21) Appl. No.: 19/752,671

(22) Filed: Jul. 24, 2026

Related U.S. Application Data
(62) Division of application No. 18/533,136, filed on Dec. 7, 2023.

(51) Int. Cl. H10W 90/00; G02B 6/12; H10W 70/65; H10W 74/10

(52) U.S. Cl. CPC H10W 90/701; G02B 6/12004; H10W 70/65; H10W 90/00; G02B 2006/12061; H10W 74/142; H10W 90/724; H10W 90/792; H10W 90/794

(57) ABSTRACT

A manufacturing method of a semiconductor package includes: providing a plurality of through vias and an embedded device over a carrier; providing an insulation body over the carrier to form an integrated interconnect structure, wherein the insulation body at least laterally encapsulates the plurality of through vias and the embedded device; removing the carrier; bonding the integrated interconnect structure over a package substrate; bonding a photonic die over the integrated interconnect structure, wherein the photonic die is coupled to the embedded device; and bonding an integrated circuit package over the integrated interconnect structure, wherein the integrated circuit package is coupled to the photonic die through the photonic die.

### CROSS-REFERENCE TO RELATED APPLICATION

This is a divisional application of Patent Application No. 18/533,136, filed on Dec., 07, 2023. The entirety of each of the above-mentioned patent applications is hereby incorporated by reference herein and made a part of this specification.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 illustrate cross sectional views of intermediate stages in the manufacturing of a semiconductor package according to some exemplary embodiments of the present disclosure.

FIGS. 11-15 illustrate cross sectional views of intermediate stages in the manufacturing of a semiconductor package according to some exemplary embodiments of the present disclosure.

FIG. 16 illustrates a cross sectional view of a semiconductor package according to some exemplary embodiments of the present disclosure.

FIG. 17 illustrates a top view of a semiconductor package according to some exemplary embodiments of the present disclosure.

FIGS. 18-23 illustrate cross sectional views of intermediate stages in the manufacturing of a semiconductor package according to some exemplary embodiments of the present disclosure.

FIGS. 24-31 illustrate cross sectional views of intermediate stages in the manufacturing of a semiconductor package according to some exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure, various aspects of a semiconductor package and the manufacturing method thereof are described. Three-dimensional (3D) packages including both optical devices and electrical devices, and the method of forming the same are provided, in accordance with some embodiments. In particular, a waveguide structure may be embedded in an integrated interconnect structure for providing an interface between electrical signals sent or received from a processing device and optical signals sent or received from an optical fiber or optical waveguide network. The electronic dies and the processing device (e.g., in an integrated circuit package) are bonded to the integrated interconnect structure that facilitates transmission of electrical signals between the electronic dies and the processing device. The integrated interconnect structure may be formed of a composite material or a molding compound, and may include embedded interconnect devices that allow for improved high-speed transmission of electrical signals. The intermediate stages of forming the semiconductor packages are illustrated, in accordance with some embodiments. Some variations of some embodiments are discussed. Throughout the various views and illustrative embodiments, like reference numbers are used to designate like elements.

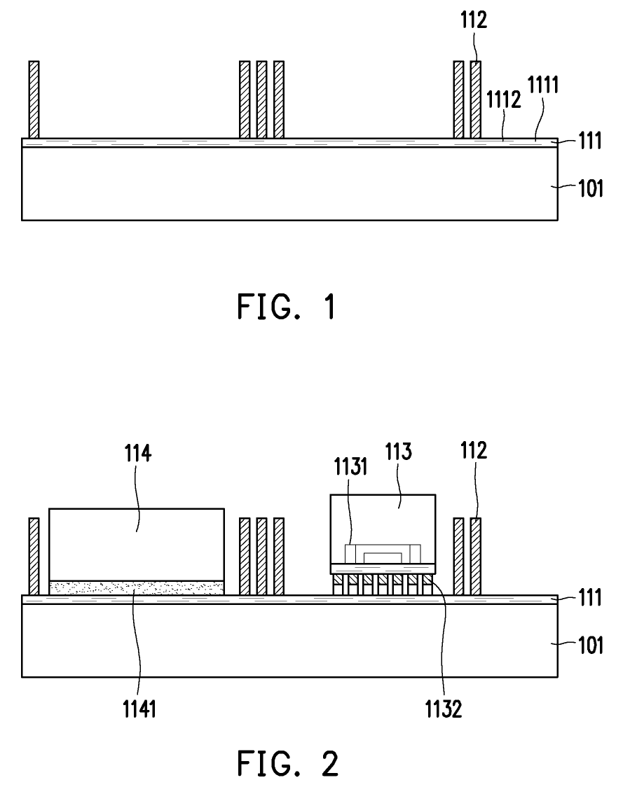

FIGS. 1-10 illustrate cross sectional views of intermediate stages in the manufacturing of a semiconductor package according to some exemplary embodiments of the present disclosure. Referring to FIG. 1, in some embodiments, a first carrier 101 is provided, and a plurality of through vias 112 is provided over the first carrier 101. The first carrier 101 may be a glass carrier substrate, a ceramic carrier substrate, a wafer (e.g., a silicon wafer), or the like. In the present embodiment, the first carrier 101 may be in a wafer form, such that multiple packages can be formed on the first carrier 101 simultaneously. In some embodiments, a release layer (not shown) may be formed over the first carrier 101. The release layer may be formed of a polymer-based material, which may be removed along with the first carrier 101 from the overlying structures that will be formed in subsequent steps. In some embodiments, the release layer is an epoxy-based thermal-release material, which loses its adhesive property when heated, such as a light-to-heat-conversion (LTHC) release coating. In other embodiments, the release layer may be an ultra-violet (UV) glue, which loses its adhesive property when exposed to UV lights. The release layer may be dispensed as a liquid and cured, may be a laminate film laminated onto the first carrier 101, or may be the like. The top surface of the release layer may be leveled and may have a high degree of planarity.

In accordance with some embodiments of the disclosure, before the through vias 112 are formed over the first carrier 101, a first redistribution structure 111 including dielectric layer 1111 and metallization pattern 1112 is formed. In some embodiments, the dielectric layer 111 is formed of a polymer, such as polybenzoxazole (PBO), polyimide, benzocyclobutene (BCB), or the like. In other embodiments, the dielectric layer 104 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 1111 may be formed by any acceptable deposition process, such as spin coating, chemical vapor deposition (CVD), laminating, the like, or a combination thereof.

The metallization pattern 1112 is formed on the dielectric layer 1111. As an example to form metallization pattern 1112, a seed layer (not shown) is formed over the dielectric layer 1111. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photo resist is then formed and patterned on the seed layer. The photo resist may be formed by spin coating or the like and may be exposed to light for patterning. The pattern of the photo resist corresponds to the metallization pattern 1112. The patterning forms openings through the photo resist to expose the seed layer. A conductive material is formed in the openings of the photo resist and on the exposed portions of the seed layer. The conductive material may be formed by plating, such as electroplating or electroless plating, or the like. The conductive material may comprise a metal, like copper, titanium, tungsten, aluminum, or the like. Then, the photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as by wet or dry etching. The remaining portions of the seed layer and conductive material form the metallization pattern 1112.

As illustrated, the first redistribution structure 111 includes a dielectric layer 1111 and a metallization pattern 1112. In other embodiments, the first redistribution structure 111 can include any number of dielectric layers, metallization patterns, and vias. One or more additional metallization pattern and dielectric layer may be formed in the first redistribution structure 111 by repeating the processes for forming a metallization patterns 1112 and dielectric layer 1111. Vias may be formed during the formation of a metallization pattern by forming the seed layer and conductive material of the metallization pattern in the opening of the underlying dielectric layer. The vias may therefore interconnect and electrically couple the various metallization patterns.

Continuing with FIG. 1, the through vias 112 are formed over the first carrier 101. In the embodiments, the through vias 112 are formed over the first redistribution structure 111. As an example to form the through vias 112, a seed layer is formed over the first redistribution structure 111. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photo resist is formed and patterned on the seed layer. The photo resist may be formed by spin coating or the like and may be exposed to light for patterning. The pattern of the photo resist corresponds to through vias. The patterning forms openings through the photo resist to expose the seed layer. A conductive material is formed in the openings of the photo resist and on the exposed portions of the seed layer. The conductive material may be formed by plating, such as electroplating or electroless plating, or the like. The conductive material may comprise a metal, like copper, titanium, tungsten, aluminum, or the like. The photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as by wet or dry etching. The remaining portions of the seed layer and conductive material form through vias 112.

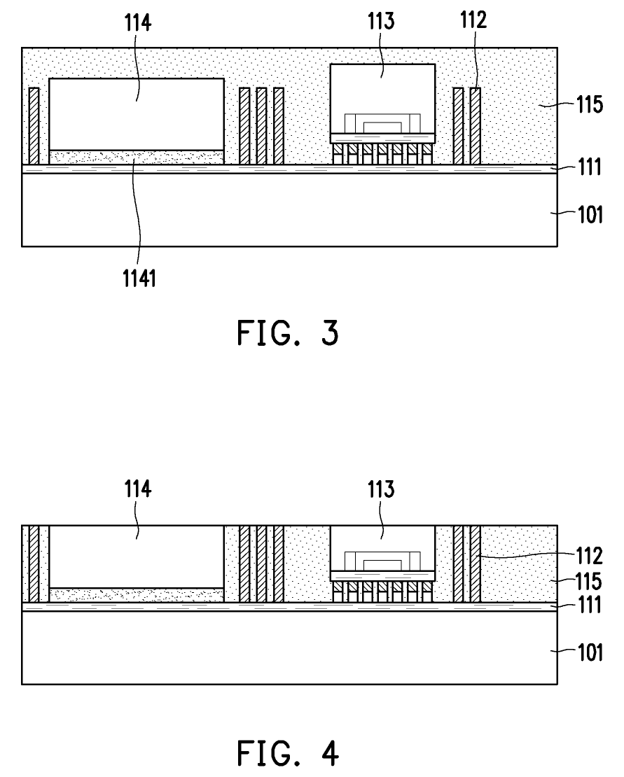

In FIG. 2, at least one embedded device is provided over the first carrier 101. In some embodiments, the embedded device may be attached to the first redistribution structure 111. In the present embodiment, the embedded device includes an interconnect device 113 and a dummy die 114, which is electrically insulated from the interconnect device 113 and the through vias 112. In other embodiments, the embedded device may include an electronic die, a dummy die, a waveguide, any combination thereof, or the like. The embedded device may be placed on the first redistribution structure 111 using, e.g., a pick-and-place process. FIG. 2 illustrates one interconnect device 113, but in other embodiments, more than one interconnect device 113 may be attached.

In embodiments in which multiple interconnect device 113 are attached, the interconnect device 113 may have different sizes (e.g., different heights and/or surface areas), or may have the same size (e.g., same heights and/or surface areas). In one embodiment, the interconnect device 113 is an interconnect die, which is free from active devices such as transistors and diodes. The interconnect die may or may not be free from passive devices such as capacitors, transformers, inductors, resistors, and the like. In accordance with alternative embodiments of the present disclosure, the interconnect die include some active devices and/or passive devices (not shown), and the active devices may be formed at the top surfaces of semiconductor substrates. The interconnect device 113 have the function of interconnecting the subsequently bonded optical engine module 120 and integrated circuit package 130 (shown in FIG. 10). In accordance with some embodiments of the present disclosure, the interconnect device 113 may include a substrate, which may be a semiconductor substrate such as a silicon substrate. The substrate may also be a dielectric substrate, which is formed of a dielectric material such as silicon oxide, silicon nitride, or the like. In accordance with some embodiments of the present disclosure, there is no through-via formed to penetrate through the substrate, regardless of whether the substrate is formed of a semiconductor or a dielectric material.

In some embodiments, the interconnect device 113 may include interconnect structures, which further includes dielectric layers and metal lines and vias 1131 in dielectric layers. Dielectric layers may include Inter-Metal Dielectric (IMD) layers. In accordance with some embodiments of the present disclosure, some lower ones of dielectric layers are formed of a low-k dielectric material. The metal lines and vias 1131 are formed in dielectric layers. The formation process may include single damascene and dual damascene processes. In an exemplary single damascene process, trenches are first formed in one of dielectric layers, followed by filling the trenches with a conductive material. A planarization process such as a Chemical Mechanical Polish (CMP) process is then performed to remove the excess portions of the conductive material higher than the top surface of the corresponding dielectric layer, leaving metal lines in the trenches. In a dual damascene process, both trenches and via openings are formed in an IMD layer, with the via openings underlying and connected to the trenches. The conductive material is then filled into the trenches and the via openings to form metal lines and vias, respectively. The conductive material may include a diffusion barrier layer and a copper-containing metallic material over the diffusion barrier layer. The diffusion barrier layer may include titanium, titanium nitride, tantalum, tantalum nitride, or the like. Metal lines and vias 1131 may also include some portions formed in passivation layers.

In the embodiment, the interconnect device 113 may be oriented with the conductive connectors 1132, connecting the metal lines and vias 1131, facing toward the first carrier 101, as shown in FIG. 2. Different interconnect device 113 may be bonded over the first carrier 101 in different orientations. In some embodiments, the dummy die 114 may be attached to first redistribution structure 111 through a die attach film (DAF) 1141, which is an adhesive film. The dummy die 114 may be configured to adjust the amount of the insulation body that is subsequently formed, so as to reduce issues of thermal stress and warpage. Throughout the description, the term “dummy die” refers to the die or chip that does not have any electrical function, and the dummy die does not contribute to the electrical operation of the resulting package. The dummy die may be formed of a homogenous material without any circuit, metal line, and/or sub-layer therein.

In some embodiments, the dummy die 114 may be formed of glass, quartz, blank silicon, or the like. The Coefficient of Thermal Expansion (CTE) of dummy die 114 is lower than the CTE of insulation body 115, which will be formed later in FIG. 3 to be molded between the interconnect device 113 and the dummy die 114. In the embodiments of the present disclosure, by placing the dummy die 114 over the first carrier 101 along with the interconnect device 113, the dummy die 114 occupies the space that otherwise will be occupied by a molding compound (i.e., insulation body 115 shown in FIG. 3). Since the dummy die 114 have a CTE smaller than the CTE of the molding compound, the overall CTE of the layer that includes the molding compound, the interconnect device 113, and the dummy die 114 is reduced compared to the layer that does not include the dummy die. Since the CTE of the molding compound is much higher than the CTE of the carrier, during the manufacturing process, the carrier and the molding compound has warpage, which affects the manufacturing process, and sometimes makes the processes infeasible. Accordingly, by reducing the overall CTE through the addition of dummy die 114, the warpage is reduced.

Then, referring to FIG. 3, an insulation body 115 is provided (formed) over the first carrier 101. After formation, the insulation body 115 at least laterally encapsulates the plurality of through vias 112 and the embedded device (e.g., the interconnect device 113 and dummy die 114). The insulation body 115 may be a molding compound, epoxy, or the like. The insulation body 115 may be applied by compression molding, transfer molding, lamination, or the like, and may be formed over the first carrier 101 such that the through vias 112 and/or the embedded device such as the interconnect device 113 and the dummy die 114 are buried or covered. The insulation body 115 is further formed in gap regions between the through vias 112, the interconnect device 113 and/or the dummy dies 114. The insulation body 115 may be applied in liquid or semi-liquid form and then subsequently cured.

In FIG. 4, a planarization process is performed on the insulation body 115 to expose the through vias 112 and the back surfaces of the interconnect device 113 and the dummy die 114. The back surfaces of the through vias 112, the interconnect device 113 and the dummy die 114 may be coplanar with the ground surface of the insulation body 115 after the planarization process. The planarization process may be, for example, a chemical-mechanical polish (CMP), a grinding process, or the like. In some embodiments, the planarization may be omitted, for example, if the through vias 112 and/or the back surfaces of the interconnect device 113 and the dummy die 114 are already exposed. Accordingly, from a structural point of view, the through vias 112 extend through the insulation body 115 after the planarization process.

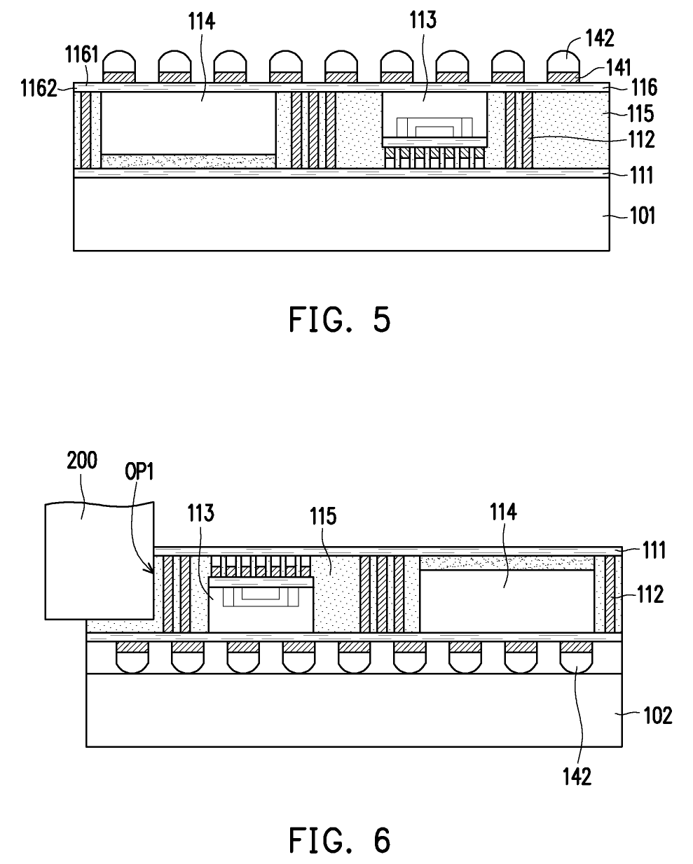

In FIG. 5, a second redistribution structure 116 is formed. The second redistribution structure 116 includes metallization pattern 1161 and dielectric layer 1162. The dielectric layer 1162 may be formed over the insulation body 115, the through vias 112, the interconnect device 113, and the dummy die 114. In some embodiments, the dielectric layer 1162 is formed of a polymer, such as polybenzoxazole (PBO), polyimide, benzocyclobutene (BCB), or the like. In other embodiments, the dielectric layer 1162 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 1162 may be formed by any acceptable deposition process, such as spin coating, CVD, laminating, the like, or a combination thereof.

The metallization pattern 1161 may be formed on/in the dielectric layer 1162. As an example to form metallization pattern 1161, a seed layer is formed over the dielectric layer 1162. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist is then formed and patterned on the seed layer. The photoresist may be formed by spin coating or the like and may be exposed to light for patterning. The pattern of the photoresist corresponds to the metallization pattern 1161. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 1161.

It should be appreciated that the second redistribution structure 116 may include any number of dielectric layers and metallization patterns. If more dielectric layers and metallization patterns are to be formed, steps and processes similar to those discussed above may be repeated. The metallization patterns may include conductive lines and conductive vias. The conductive vias may be formed during the formation of the metallization pattern by forming the seed layer and conductive material of the metallization pattern in the opening of the underlying dielectric layer. The conductive vias may therefore interconnect and electrically couple the various conductive lines.

In FIG. 5, a plurality of under-bump metallizations (UBMs) 141 and a plurality of conductive connectors 142 are formed for external connection to the second redistribution structure 116, in accordance with some embodiments. The UBMs 141 have bump portions on and extending along the major surface of the dielectric layer 1162, and have via portions extending through the dielectric layer 1611 to physically and electrically couple the metallization pattern 1161. As a result, the UBMs 141 are electrically coupled to the through vias 112 and the interconnect devices 113. The UBMs 141 may be formed of the same material as the metallization pattern 1161, and may be formed using a similar process (e.g., plating). In some embodiments, the UBMs 141 have a different size (e.g., width, thickness, etc.) than the metallization pattern 1161.

The conductive connectors 142 are then formed on the UBMs 141, in accordance with some embodiments. The conductive connectors 142 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 142 may include a conductive material such as solder, copper, aluminum, gold, nickel, silver, palladium, tin, the like, or a combination thereof. In some embodiments, the conductive connectors 142 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 142 include metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Then, in FIG. 6, the first carrier 101 is removed. In some embodiments, a de-bonding process is performed to detach (or “de-bond”) the first carrier 101 from the overlying structure. In accordance with some embodiments, the de-bonding includes projecting a light such as a laser light or an UV light on the release layer so that the release layer decomposes under the heat of the light and the first carrier 101 can be removed. The structure is then flipped over and attached to a second carrier 102, as shown in FIG. 6. The second carrier substrate 102 may be a glass carrier substrate, a ceramic carrier substrate, a wafer (e.g., a silicon wafer), or the like. An adhesive layer or a release layer (not shown in FIG. 6) may be formed on the second carrier 102 to facilitate the attaching of the structure.

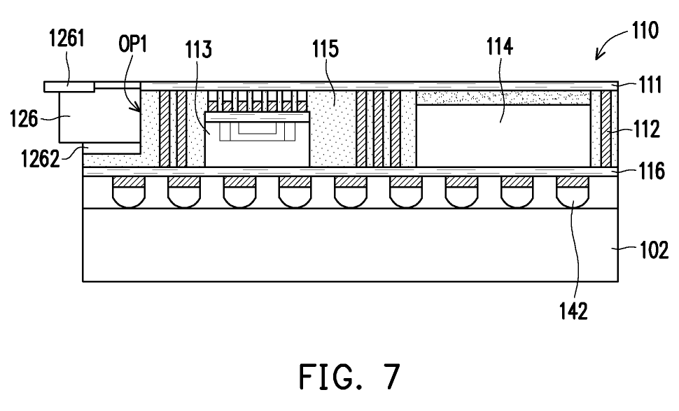

Continuing with FIG. 6, in some embodiments, a concave OP1 is formed on an outer edge of the insulation body 115. In some embodiments, the concave OP1 may be formed by trimming process by a trimming tool 200. In other embodiments, the concave OP1 may be formed by an etch process, or the like. Referring to FIG. 7, then, a waveguide 126 is disposed in the concave OP1. In some embodiments, the waveguide 126 may be attached to a bottom surface of the concave OP1 through the adhesive film 1262 such as die attach film (DAF). In some embodiments, the waveguide 126 is an optical dielectric waveguide, but is not limited thereto. In some embodiments, a material of the waveguide 126 includes glass such as spin-on glass (SOG), silicon, silicon oxide, photoresist, epoxy, optical polymer such as polymethylmethacrylate, polyurethane or polyimide and other suitable optical dielectric material. In the present embodiment, the waveguide 126 is made of a glass die. In some embodiments, a top surface of the waveguide 126 is coplanar with a top surface of the first redistribution structure 111.

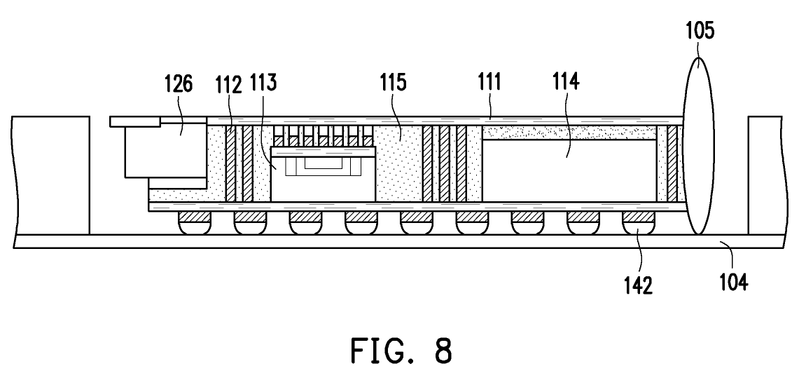

Then, referring to FIGS. 7 and 8, a de-bonding process is performed to detach (de-bond) the second carrier 102 from the conductive connectors 142. In accordance with some embodiments, the de-bonding includes projecting a light such as a laser light or an UV light on the release layer so that the release layer decomposes under the heat of the light and the second carrier 102 can be removed. The structure is then flipped over and placed on a tape 104. Then, a singulation process is performed by using sawing tool 105 to dice along scribe line regions. Accordingly, a plurality of integrated interconnect structures 110 (one is illustrated herein) separated from one another are formed.

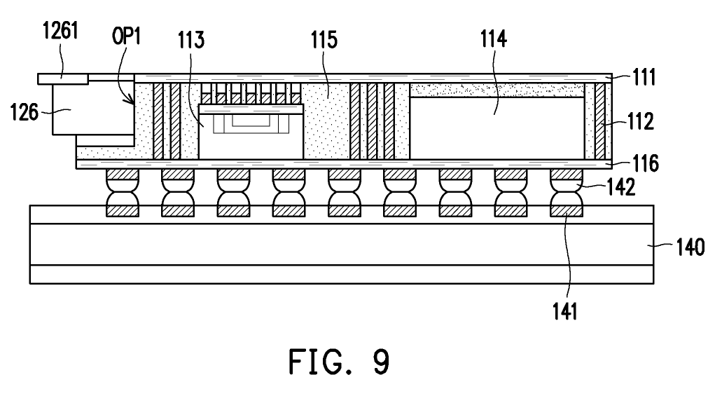

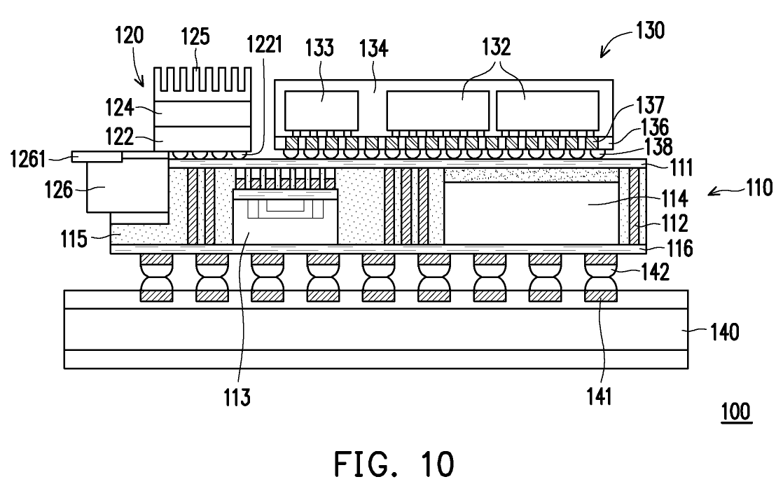

Then, referring to FIG. 9, the integrated interconnect structure 110 is flipped over, and bonded over a package substrate 140, in accordance with some embodiments. The integrated interconnect structure 110 is mounted to the package substrate 140 using a plurality of conductive connectors 142. The package substrate 140 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the package substrate 400 may be a SOI substrate. Generally, an SOI substrate includes a layer of a semiconductor material such as epitaxial silicon, germanium, silicon germanium, SOI, SGOI, or combinations thereof. The package substrate 140 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for package substrate 140.

The package substrate 140 may include active and passive devices (not shown). As one of ordinary skill in the art will recognize, a wide variety of devices such as transistors, capacitors, resistors, combinations of these, and the like may be used to generate the structural and functional requirements of the design for the semiconductor package. The devices may be formed using any suitable methods.

The package substrate 140 may also include metallization layers and vias (not shown) and bond pads 141 over the metallization layers and vias. The metallization layers may be formed over the active and passive devices and are designed to connect the various devices to form functional circuitry. The metallization layers may be formed of alternating layers of dielectric (e.g.¸ low-k dielectric material) and conductive material (e.g., copper) with vias interconnecting the layers of conductive material and may be formed through any suitable process (such as deposition, damascene, dual damascene, or the like). In some embodiments, the package substrate 140 is substantially free of active and passive devices.

In some embodiments, the conductive connectors 142 can be reflowed to attach the integrated interconnect structure 110 to the bond pads 141. The conductive connectors 142 are electrically and/or physically couple the package substrate 140, including metallization layers in the package substrate 140, to the integrated interconnect structure 110.

The conductive connectors 142 may have an epoxy flux (not shown) formed thereon before they are reflowed with at least some of the epoxy portion of the epoxy flux remaining after the integrated interconnect structure 110 is attached to the package substrate 140. This remaining epoxy portion may act as an underfill to reduce stress and protect the joints resulting from the reflowing the conductive connectors 142. In some embodiments, an underfill (not shown) may be formed between the integrated interconnect structure 110 and the package substrate 140 and surrounding the conductive connectors 142. The underfill may be formed by a capillary flow process after the package substrate 140 is attached or may be formed by a suitable deposition method before the integrated interconnect structure 110 is attached.

Then, referring to FIG. 10, an electronic die 122 and a photonic die 124 are bonded over the integrated interconnect structure 110 and coupled to the embedded device (e.g., the interconnect device 113 and the waveguide 126). In one embodiment, the electronic die 122 is bonded to the integrated interconnect structure 110, and the photonic die 124 is stacked over and bonded to the electronic die 122 and the waveguide 126. The bonding between the electronic die 122 and the photonic die 124 may include, for example, hybrid bonding, fusion bonding, direct bonding, dielectric bonding, metal bonding, solder joints (e.g., microbumps), or the like. The electronic die 122, the photonic die 124, and the waveguide 126 may be seen as an optical engine module 120. In addition, an integrated circuit package 130 is bonded over the integrated interconnect structure 110 and electrically coupled to the optical engine module 120. In some embodiments, the optical engine module 120 is configured to receive optical signals from an optical device (e.g., an optical fiber 150 shown in FIG. 16) through pins 1261 of the waveguide 126. The photonic die 124 is optically coupled to the optical device 150 through the waveguide 126. In some embodiments, a portion of the optical engine module 120 is embedded in the integrated interconnect structure 110. For example, in the present embodiment, the waveguide 126 is embedded in the integrated interconnect structure 110. In some embodiments, a heat dissipation device 125 such as a heat sink may be disposed on the photonic die 124 of the optical engine module 120 to facilitate heat dissipation. In some embodiments, the integrated interconnect structure 110 may be an interposer. That is, the integrated interconnect structure 110 may be an integrated interposer structure.

In general, the optical signals are detected using the photodetector of the photonic die 124. The electronic die 122 in the optical engine module 120 may then generate corresponding electrical signals based on the optical signals. These electrical signals may then be transmitted to a processing die 132 in the integrated circuit package 130 through the interconnect device 113 of the integrated interconnect structure 110. The processing die 132 may then process the electrical signals or provide other appropriate computing functionality. In some embodiments, the processing die 132 generates electrical signals that may be transmitted to the electronic die 122 of the optical engine module 120 through an interconnect device 113 of the integrated interconnect structure 110. The electronic die 122 may then generate optical signals using a modulator and couple these optical signals into an optical fiber 150 through waveguide 126. In some embodiments, the processing die 132 controls the electronic die 122 of the optical engine module 120. In this manner, the optical engine module 120 may be considered an “optical input/output (I/O) module” for the semiconductor package 100.

In FIG. 10, the electronic die 122 is bonded to the first redistribution structure 111 of the integrated interconnect structure 110, in accordance with some embodiments. The electronic dies 122 may be, for example, semiconductor devices, dies, or chips that communicate with the photonic die 124 using electrical signals. One electronic die 122 is shown in FIG. 10, but the optical engine module 120 may include two or more electronic dies 122 in other embodiments. The electronic die 122 includes die connectors 1221, which may be, for example, conductive pads, conductive pillars, or the like.

The electronic die 122 may include integrated circuits for interfacing with the photonic die 124, such as circuits for controlling the operation of the photonic die 124. For example, the electronic die 122 may include controllers, drivers, trans-impedance amplifiers, the like, or combinations thereof. The electronic die 122 may also include a CPU, in some embodiments. In some embodiments, the electronic die 122 includes circuits for processing electrical signals received from the photonic die 124, such as for processing electrical signals received from a photodetector of the photonic die 124. The electronic die 122 may control high-frequency signaling of the photonic die 124 according to electrical signals (digital or analog) received from another device, such as from the processing die 132 of the integrated circuit package. In some embodiments, the electronic die 122 may be an electronic integrated circuit (EIC) or the like that provides Serializer/Deserializer (SerDes) functionality. In this manner, the electronic die 122 may act as part of an I/O interface between optical signals and electrical signals within a semiconductor package 100.

In some embodiments, the electronic die 122 may be bonded to the first redistribution structure 111 through the die connectors 1221. In some embodiments, the electronic die 122 may be bonded to the first redistribution structure 111 by dielectric-to-dielectric bonding and/or metal-to-metal bonding (e.g., direct bonding, fusion bonding, oxide-to-oxide bonding, hybrid bonding, or the like). In such embodiments, covalent bonds may be formed between oxide layers, such as the topmost dielectric layers and surface dielectric layers (not shown) of the electronic die 122. During the bonding, metal bonding may also occur between the die connectors 1221 of the electronic die 122 and the conductive pads of the first redistribution structure 111. The use of dielectric-to-dielectric bonding may allow for materials transparent to the relevant wavelengths of light to be deposited over the first redistribution structure 111 and/or around the electronic die 122 instead of opaque materials such as an encapsulant or a molding compound. For example, the dielectric material may be formed from a suitably transparent material such as silicon oxide instead of an opaque material such as a molding compound. The use of a suitably transparent material for the dielectric material in this manner allows optical signals to be transmitted through the dielectric material, such as transmitting optical signals between an optical coupler of the waveguide 126 and an optical fiber to be coupled to the waveguide 126. Additionally, by bonding the electronic die 122 to the first redistribution structure 111 in this manner, the thickness of the resulting semiconductor package 100 may be reduced, and the optical coupling between the waveguide 126 and the optical fiber (e.g., the optical fiber shown in FIG. 16) may be improved. In this manner, the size or processing cost of the semiconductor package 100 may be reduced, and the optical coupling to external components may be improved. In some embodiments, the semiconductor package 100 described herein could be considered system-on-chip (SoC) or system-on-integrated-circuit (SoIC) devices.

In FIG. 10, the integrated circuit package 130 is also bonded to an upper side of the integrated interconnect structure 110, opposite the package substrate 140. The conductive connectors 138 are used to attach the connectors 137 of the integrated circuit package 130 to the conductive lines of the integrated interconnect structure 110. Attaching the integrated circuit package 130 may include placing the integrated circuit package 130 on the conductive connectors 138 and reflowing the conductive connectors 138 to physically and electrically couple the integrated circuit package 130 and the integrated interconnect structure 110. At this point, a manufacturing process of the semiconductor package 100 may be substantially done.

The interconnect device 113 provides electrical connection between devices attached to the integrated interconnect structure 110 in the semiconductor package 100, such as between the optical engine module 120 and the integrated circuit package 130 including at least one processing die 132 and/or at least one memory die 133. In some embodiments, the interconnect device 113 may include through-substrate vias (TSVs) to make electrical connections between conductive features on opposite sides of the interconnect device 113. The TSVs of the interconnect device 113 are optional, and may not be present in some embodiments. The interconnect device 113 may be formed using applicable manufacturing processes. The interconnect device 113 may be free of active devices and/or free of passive devices.

The integrated circuit package 130 shown in FIG. 10 includes two processing die 132 and a memory die 133, though in other embodiments the integrated circuit package 130 may include more or fewer devices and/or devices of different types than these. The processing die 132 may include, for example, a central processing unit (CPU), a graphics processing unit (GPU), an application-specific integrated circuit (ASIC), a high performance computing (HPC) die, the like, or a combination thereof. The memory die 133 may include, for example, a volatile memory such as dynamic random-access memory (DRAM), static random-access memory (SRAM), another type of memory, or the like. In such embodiments, processing and memory functionality may be integrated within the same die. The processing die 132 and memory die 133 shown are example components, and the integrated circuit package 130 may include one or more semiconductor devices, chips, dies, system-on-chip (SoC) devices, system-on-integrated-circuit (SoIC) devices, the like, or a combination thereof. The processing die 132 and the memory die 133 may have a different arrangement than shown in other embodiments. These and other configurations are considered within the scope of the present disclosure.

In some embodiments, the integrated circuit package 130 further includes an interposer 136 and an encapsulating material 134. The processing die 132 and the memory die 133 are bonded over the interposer 136, and the encapsulating material 134 laterally encapsulates the processing die 132 and the memory die 133. An underfill layer (not shown) may be formed under and around the processing die 132 and the memory die 133 to encapsulate the conductive connectors for bonding the processing die 132 and the memory die 133 to the interposer 136. The underfill layer may be formed of an epoxy-based polymeric material. The encapsulating material 134 may be formed over the interposer 136 to at least laterally encapsulate the processing die 132 and the memory die 133. The encapsulating material 134 may be formed of an epoxy molding compound (EMC).

The integrated interconnect structure 110 electrically connects the optical engine module 120 and the integrated circuit package 130 and allows transmission of electrical signals between the optical engine module 120, the processing die 132, and/or the memory die 133. In some embodiments, the optical engine module 120 and the integrated circuit package 130 are electrically connected through the integrated interconnect structure 110 by the interconnect device 113. For example, the interconnect device 113 may conduct electrical signals between the processing die 132 and the optical engine module 120. The use of interconnect device 113 in this manner allows for improved high-speed communication between the optical engine module 120 and the integrated circuit package 130. For example, the interconnect device 113 may have conductive routing of a finer pitch than the conductive routing of the integrated interconnect structure 110 or of the package substrate 140, which allows for improved high-speed transmission of electrical signals. The interconnect device 113 also may be located closer to the optical engine module 120 and the integrated circuit package 130 than, for example, the package substrate 140, reducing routing distances and allowing for reduced noise, improved high-speed performance, and reduced power consumption. Multiple interconnect device 113 may be used in any suitable configuration within the integrated interconnect structure 110 of a semiconductor package 100, allowing for flexible design and the formation of the semiconductor package 100 of larger size.

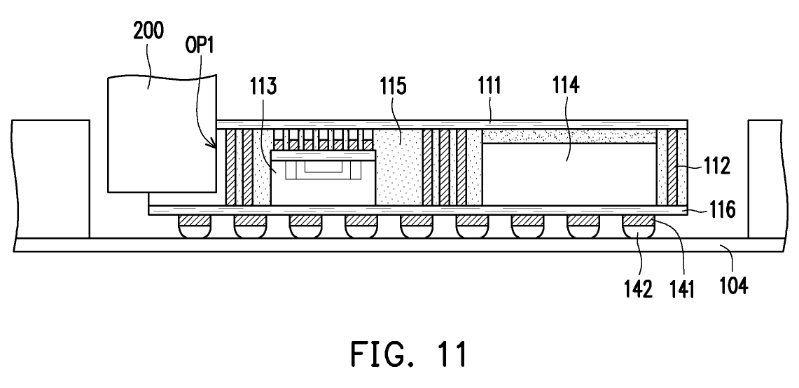

FIGS. 11-15 illustrate cross sectional views of intermediate stages in the manufacturing of a semiconductor package according to some exemplary embodiments of the present disclosure. The process shown in FIGS. 1-10 is merely one of the possible methods for forming the semiconductor package 100. FIGS. 11-15 illustrate another embodiment of manufacturing the semiconductor package. It is noted that the manufacturing method of the semiconductor package shown in FIGS. 11-15 contains many features same as or similar to the semiconductor package disclosed earlier with FIGS. 1-10. For purpose of clarity and simplicity, detail description of same or similar features may be omitted, and the same or similar reference numbers denote the same or like components.

It is noted that the steps shown in FIGS. 11-15 are performed after the step shown in FIG. 5. That is, referring to FIGS. 5 and 11, after a plurality of UBMs 141 and a plurality of conductive connectors 142 are formed over the second redistribution structure 116 as shown in FIG. 5, the resulting structure is then flipped over and placed on a tape 104 as shown in FIG. 11. The tape 104 herein may be the dicing tape 104 shown in FIG. 8. Then, a concave OP1 is formed on an outer edge of the insulation body 115. In some embodiments, the concave OP1 may be formed by trimming process by a trimming tool 200. In other embodiments, the concave OP1 may be formed by an etch process, or the like.

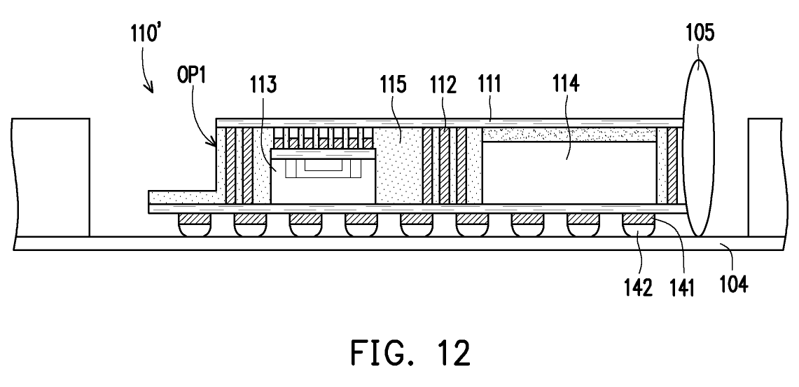

Referring to FIG. 12, then, a singulation process is performed by using sawing tool 105 to dice along scribe line regions. Accordingly, a plurality of integrated interconnect structures 110’ as shown in FIG. 12 are formed. The concave OP1 is extended toward the outermost edge of the integrated interconnect structure 110’.

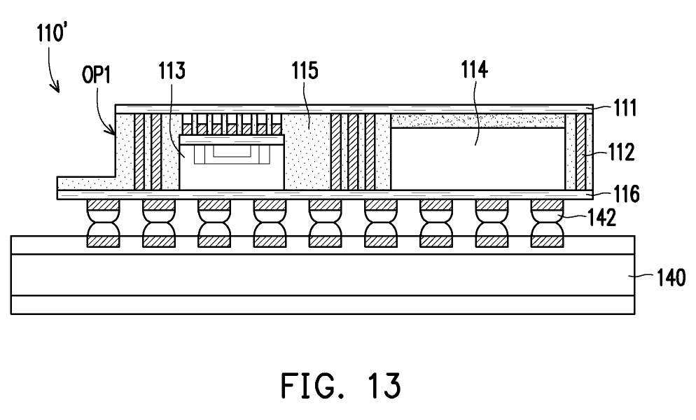

Then, referring to FIG. 13, after the singulation process, the integrated interconnect structure 110’ is flipped over, and bonded over a package substrate 140, in accordance with some embodiments. The integrated interconnect structure 110’ is mounted to the package substrate 140 using a plurality of conductive connectors 142. The package substrate 140 may be the same or similar to the package substrate 140 shown in FIG. 10, and can be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the package substrate 400 may be a SOI substrate. Generally, an SOI substrate includes a layer of a semiconductor material such as epitaxial silicon, germanium, silicon germanium, SOI, SGOI, or combinations thereof. The package substrate 400 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for package substrate 140.

The package substrate 140 may include active and passive devices (not shown). As one of ordinary skill in the art will recognize, a wide variety of devices such as transistors, capacitors, resistors, combinations of these, and the like may be used to generate the structural and functional requirements of the design for the semiconductor package. The devices may be formed using any suitable methods. In some embodiments, the conductive connectors 142 can be reflowed to attach the integrated interconnect structure 110 to the bond pads 141. The conductive connectors 142 electrically and/or physically couple the package substrate 140, including metallization layers in the package substrate 140, to the integrated interconnect structure 110.

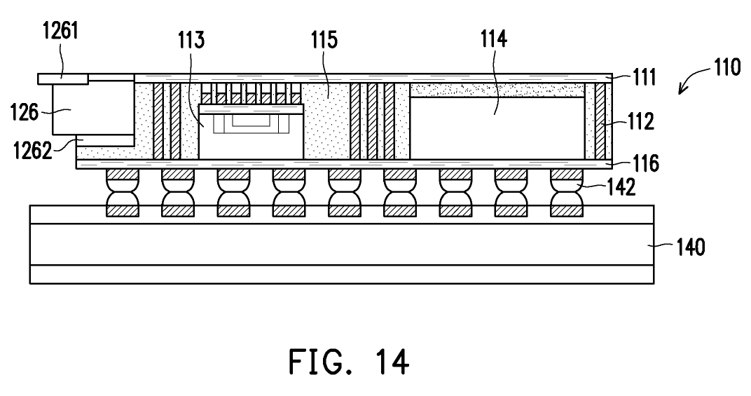

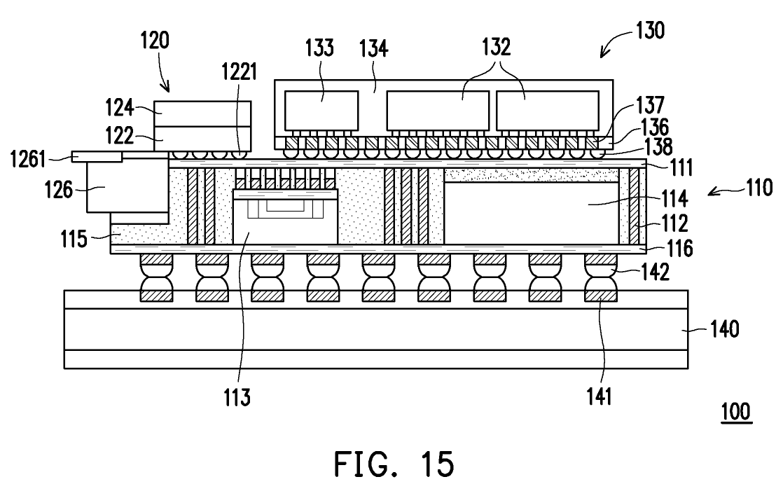

Then, referring to FIG. 14, a waveguide 126 is disposed in the concave OP1. In some embodiments, the waveguide 126 may be attached to a bottom surface of the concave OP1 through the adhesive film 1262 such as die attach film (DAF), or the like. In some embodiments, the waveguide 126 include an optical dielectric waveguide, but is not limited thereto. In some embodiments, a material of the waveguide 126 includes glass such as spin-on glass (SOG), silicon, silicon oxide, photoresist, epoxy, optical polymer such as polymethylmethacrylate, polyurethane or polyimide and other suitable optical dielectric material. In the present embodiment, the waveguide 126 is made of a glass die. In some embodiments, a top surface of the waveguide 126 is coplanar with a top surface of the first redistribution structure 111.

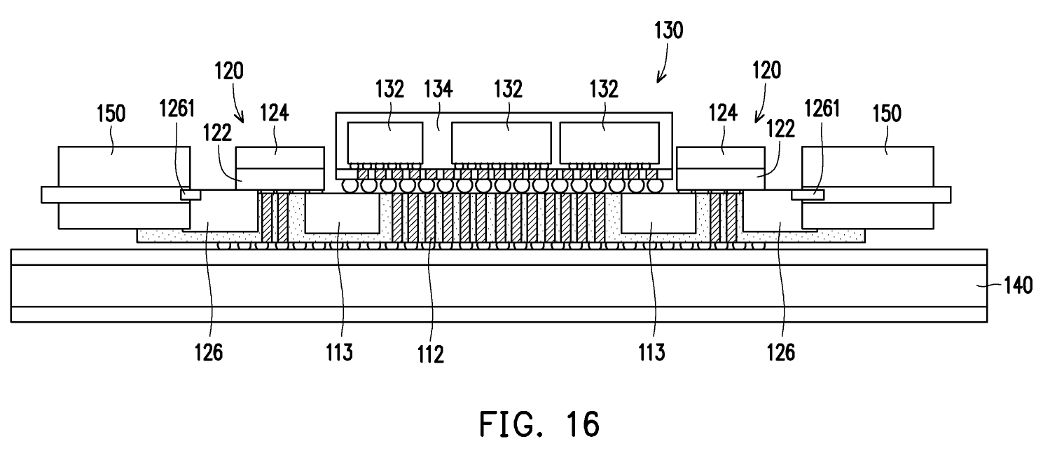

Then, referring to FIG. 15, the electronic die 122 and the photonic die 124 are bonded over the integrated interconnect structure 110 and coupled to the embedded device (e.g., the interconnect device 113 and the waveguide 126) embedded in the integrated interconnect structure 110. In one embodiment, the electronic die 122 is bonded to the integrated interconnect structure 110, and the photonic die 124 is stacked over and bonded to the electronic die 122 and the waveguide 126. The electronic die 122, the photonic die 124, and the waveguide 126 may be seen as an optical engine module 120. In addition, the integrated circuit package 130 is bonded over the integrated interconnect structure 110 and electrically coupled to the optical engine module 120. In some embodiments, the optical engine module 120 is configured to receive optical signals from an optical device (e.g., an optical fiber 150 shown in FIG. 16) through pins 1261 of the waveguide 126. The photonic die 124 is optically coupled to the optical device 150 through the waveguide 126.

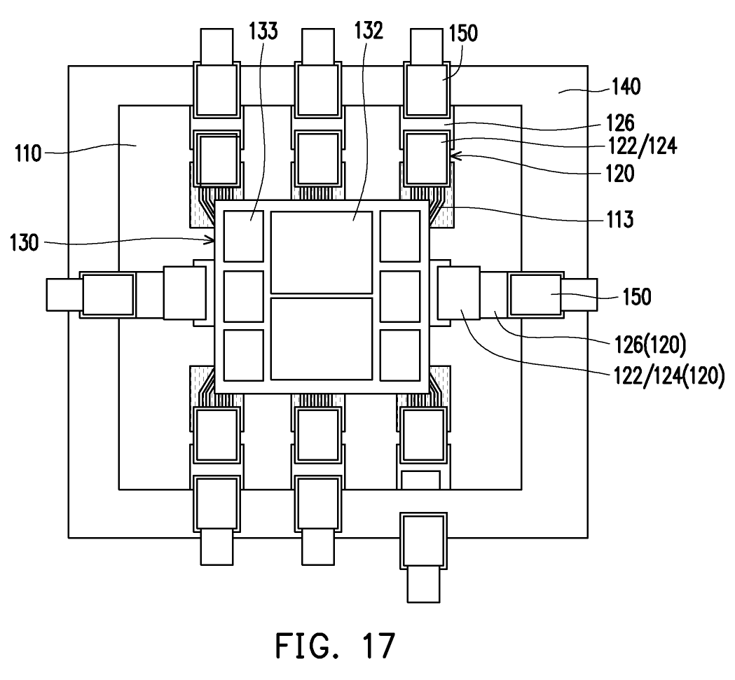

In general, the optical signals are detected using the photodetector of the photonic die 124. The electronic die 122 in the optical engine module 120 may then generate corresponding electrical signals based on the optical signals. These electrical signals may then be transmitted to a processing die 132 in the integrated circuit package 130 through the interconnect device 113 of the integrated interconnect structure 110. The processing die 132 may then process the electrical signals or provide other appropriate computing functionality. In some embodiments, the processing die 132 generates electrical signals that may be transmitted to the electronic die 122 of the optical engine module 120 through an interconnect device 113 of the integrated interconnect structure 110. The electronic die 122 may then generate optical signals using a modulator and couple these optical signals into an optical fiber 150 through waveguide 126. In some embodiments, the processing die 132 controls the electronic die 122 of the optical engine module 120. In this manner, the optical engine module 120 may be considered an “optical input/output (I/O) module” for the semiconductor package 100. Optical power may be provided to the waveguides 126 by, for example, the optical fiber 150 (see FIGS. 16 and 17) coupled to an external light source, or the optical power may be generated by a photonic component within the semiconductor package 100 such as a laser diode.

FIG. 16 illustrates a cross sectional view of a semiconductor package according to some exemplary embodiments of the present disclosure. FIG. 17 illustrates a top view of a semiconductor package according to some exemplary embodiments of the present disclosure. Referring to FIG. 16, in some embodiments, at least one optical fibers 150 may be coupled to the waveguide 126 of the optical engine module 120 by, for example, an optical glue, and/or the guide pins 1261 of the waveguide 126. A plurality of optical fibers 150 are shown in FIGS. 16 and 17 for illustrative purposes. In the embodiment, the optical fiber 150 may be an edge mounted optical fiber 150. However, in other embodiment, the optical fiber 150 may also include vertically mounted optical fibers, or a combination thereof.

Referring to FIG. 17, in some embodiments, a plurality of optical engine modules 120 surrounding the integrated circuit package 130 are attached to the integrated interconnect structure 110. The optical engine modules 120 may be electrically connected to the processing dies 132 and/or the memory dies 133 through interconnect devices 113 embedded within the integrated interconnect structure 110. The interconnect device 113 may overlap components that are connected by the interconnect device 113 from a top view. For example, the interconnect device 113 may overlap the optical engine modules 120 and the integrated circuit package 130 from a top view. To be more specific, the interconnect devices 113 may overlap and/or interconnect any two or more components, such as the optical engine modules 120, processing dies 132, and/or memory dies 133 from a top view. The interconnect devices 113 provide high-speed connections between components of the semiconductor package and thus can improve the high-speed performance of the semiconductor package.

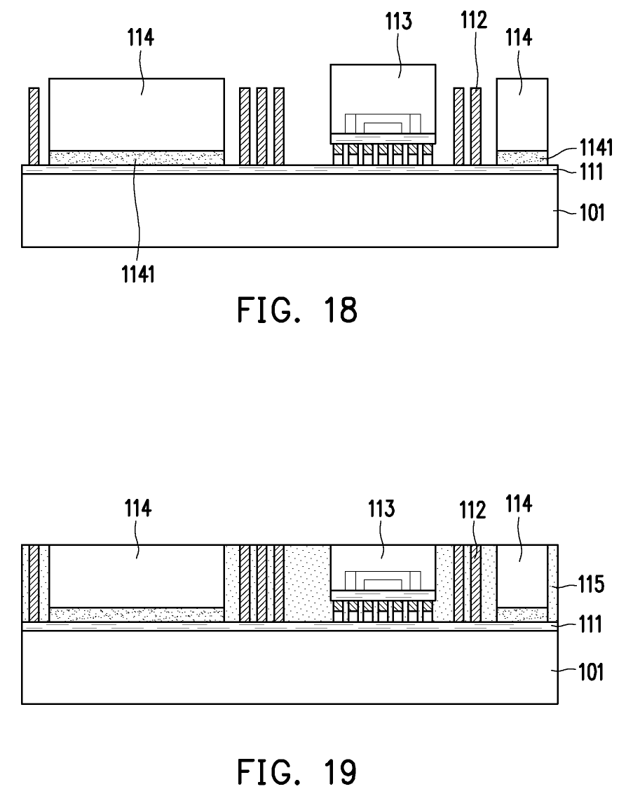

FIGS. 18-23 illustrate cross sectional views of intermediate stages in the manufacturing of a semiconductor package according to some exemplary embodiments of the present disclosure. It is noted that the manufacturing method of the semiconductor package shown in FIGS. 18-23 contains many features same as or similar to the embodiment disclosed earlier with FIGS. 1-10. For purpose of clarity and simplicity, detail description of same or similar features may be omitted, and the same or similar reference numbers denote the same or like components. In the embodiment shown in FIGS. 18-23, the optical engine module including an electronic die, a photonic die, and a waveguide may be integrated as a module and mounted over the integrated interconnect structure altogether.

Referring to FIG. 18, in some embodiments, a plurality of through vias 112 and at least one embedded device is provided over the first carrier 101. The first carrier 101 may be a glass carrier substrate, a ceramic carrier substrate, a wafer (e.g., a silicon wafer), or the like. In the present embodiment, the first carrier 101 may be in a wafer form, such that multiple packages can be formed on the first carrier 101 simultaneously. In some embodiments, a release layer (not shown) may be formed over the first carrier 101. The release layer may be removed along with the first carrier 101 from the overlying structures that will be formed in subsequent steps. The release layer may be dispensed as a liquid and cured, may be a laminate film laminated onto the first carrier 101, or may be the like. The top surface of the release layer may be leveled and may have a high degree of planarity.

In accordance with some embodiments of the disclosure, before the through vias 112 and the embedded device are provided over the first carrier 101, the first redistribution structure 111 is formed. In some embodiments, the through vias 112 are formed over the first redistribution structure 111. As an example to form the through vias 112, a seed layer is formed over the first redistribution structure 111. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photo resist is formed and patterned on the seed layer. The photo resist may be formed by spin coating or the like and may be exposed to light for patterning. The pattern of the photo resist corresponds to through vias. The patterning forms openings through the photo resist to expose the seed layer. A conductive material is formed in the openings of the photo resist and on the exposed portions of the seed layer. The conductive material may be formed by plating, such as electroplating or electroless plating, or the like. The conductive material may comprise a metal, like copper, titanium, tungsten, aluminum, or the like. The photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as by wet or dry etching. The remaining portions of the seed layer and conductive material form through vias 112.

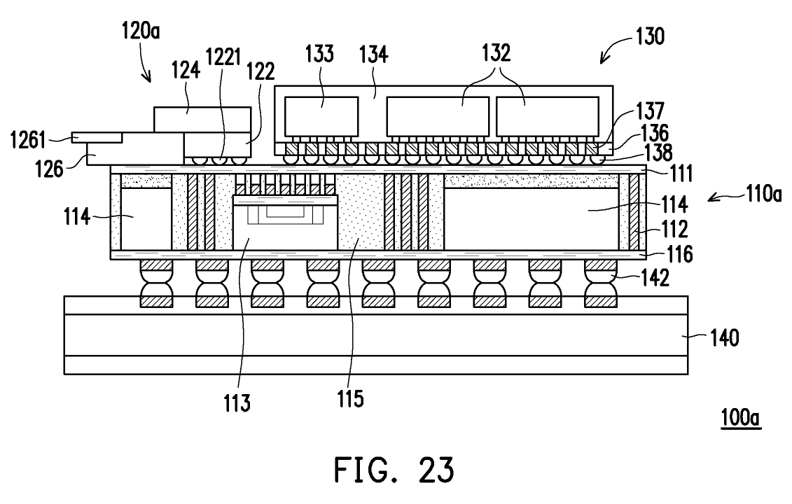

In some embodiments, the embedded device may be attached to the first redistribution structure 111. In the present embodiment, the embedded device includes an interconnect device 113 and at least one dummy die 114, which is electrically insulated from the interconnect device 113 and the through vias 112. The embedded device may be placed on the first redistribution structure 111 using, e.g., a pick-and-place process. FIG. 18 illustrates one interconnect device 113 and two dummy dies 114, but in other embodiments, more than one interconnect device 113 may be attached. In one embodiment, the interconnect device 113 is an interconnect die, which is free from active devices such as transistors and diodes. The interconnect die may or may not be free from passive devices such as capacitors, transformers, inductors, resistors, and the like. In accordance with alternative embodiments of the present disclosure, the interconnect die include some active devices and/or passive devices (not shown), and the active devices may be formed at the top surfaces of semiconductor substrates. The interconnect device 113 have the function of interconnecting the subsequently bonded optical engine module 120 and integrated circuit package 130 (shown in FIG. 23).

In the embodiment, the interconnect device 113 may be oriented with the conductive connectors 1132, connecting the metal lines and vias 1131, facing toward the first carrier 101, as shown in FIG. 18. In some embodiments, the dummy dies 114 may be attached to first redistribution structure 111 through a die attach film (DAF) 1141, which is an adhesive film. The dummy die 114 may be disposed at any space between the through vias 112 and configured to adjust the amount of the insulation body that is subsequently formed, so as to reduce issues of thermal stress and warpage.

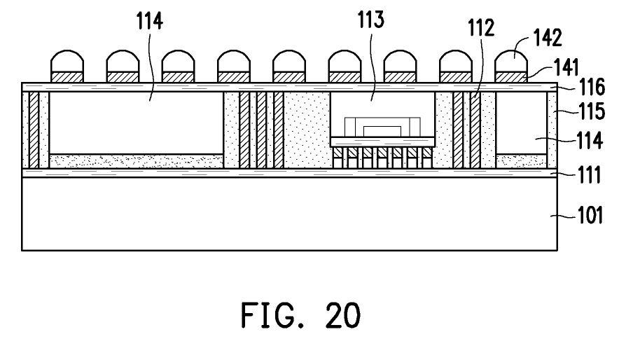

Then, referring to FIG. 19, an insulation body 115 is provided (formed) over the first carrier 101. After formation, the insulation body 115 at least laterally encapsulates the plurality of through vias 112 and the embedded device (e.g., the interconnect device 113 and dummy dies 114). The insulation body 115 may be a molding compound, epoxy, or the like. The insulation body 115 may be applied by compression molding, transfer molding, lamination, or the like, and may be formed over the first carrier 101 such that the through vias 112 and/or the embedded device such as the interconnect device 113 and the dummy dies 114 are buried or covered. The insulation body 115 may be applied in liquid or semi-liquid form and then subsequently cured.

Then, a planarization process is performed on the insulation body 115 to expose the through vias 112 and the back surfaces of the interconnect device 113 and the dummy die 114. The back surfaces of the through vias 112, the interconnect device 113 and the dummy die 114 may be coplanar with the ground surface of the insulation body 115 after the planarization process. The planarization process may be, for example, a chemical-mechanical polish (CMP), a grinding process, or the like. In some embodiments, the planarization may be omitted, for example, if the through vias 112 and/or the back surfaces of the interconnect device 113 and the dummy die 114 are already exposed. Accordingly, from a structural point of view, the through vias 112 extend through the insulation body 115 after the planarization process.

Referring to FIG. 20, the second redistribution structure 116 is formed. It should be appreciated that the second redistribution structure 116 may include any number of dielectric layers and metallization patterns. If more dielectric layers and metallization patterns are to be formed, steps and processes similar to those discussed above may be repeated. The metallization patterns may include conductive lines and conductive vias. The conductive vias may be formed during the formation of the metallization pattern by forming the seed layer and conductive material of the metallization pattern in the opening of the underlying dielectric layer. The conductive vias may therefore interconnect and electrically couple the various conductive lines.

In FIG. 20, a plurality of under-bump metallizations (UBMs) 141 and a plurality of conductive connectors 142 are formed for external connection to the second redistribution structure 116, in accordance with some embodiments. As a result, the UBMs 141 are electrically coupled to the through vias 112 and the interconnect devices 113. The conductive connectors 142 are then formed on the UBMs 141, in accordance with some embodiments. The conductive connectors 142 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 142 may include a conductive material such as solder, copper, aluminum, gold, nickel, silver, palladium, tin, the like, or a combination thereof. In some embodiments, the conductive connectors 142 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 142 include metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

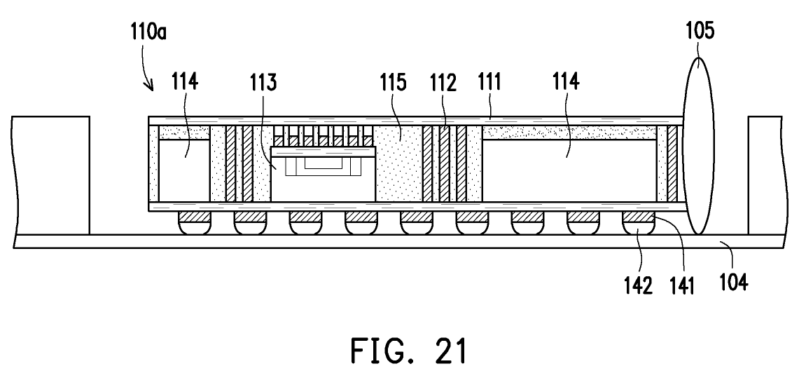

Then, referring to FIGS. 20 and 21, a de-bonding process is performed to detach (de-bond) the first carrier 101 from the conductive connectors 142. The structure is then flipped over and placed on a tape 104. Then, a singulation process is performed by using sawing tool 105 to dice along scribe line regions. Accordingly, a plurality of integrated interconnect structures 110a (one is illustrated herein) separated from one another are formed.

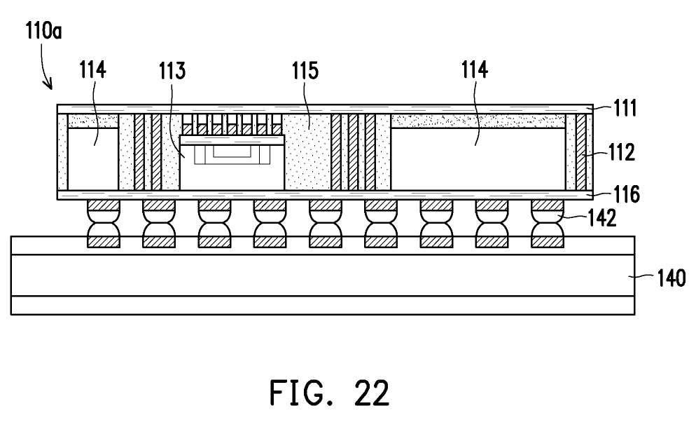

Then, referring to FIG. 22, the integrated interconnect structure 110 is flipped over, and bonded over a package substrate 140, in accordance with some embodiments. The integrated interconnect structure 110 is mounted to the package substrate 140 using a plurality of conductive connectors 142. The package substrate 140 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the package substrate 400 may be a SOI substrate. Generally, an SOI substrate includes a layer of a semiconductor material such as epitaxial silicon, germanium, silicon germanium, SOI, SGOI, or combinations thereof. The package substrate 400 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for package substrate 140. In some embodiments, the conductive connectors 142 can be reflowed to attach the integrated interconnect structure 110a to the bond pads 141.

Then, referring to FIG. 23, the optical engine module 120a including an electronic die 122, a photonic die 124 and a waveguide 126 is disposed and bonded over the integrated interconnect structure 110a and coupled to the interconnect device 113. In one embodiment, the waveguide 126 and the electronic die 122 are bonded to an upper surface of the integrated interconnect structure 110a, and the photonic die 124 is stacked over and coupled to the electronic die 122 and the waveguide 126. In addition, the integrated circuit package 130 is bonded over the integrated interconnect structure 110 and electrically coupled to the optical engine module 120a. In some embodiments, the optical engine module 120ais configured to receive optical signals from an optical device (e.g., an optical fiber 150 shown in FIG. 16) through pins 1261 of the waveguide 126. The photonic die 124 is optically coupled to the optical device 150 through the waveguide 126. The dummy dies 114 may be located under the waveguide of the optical engine module 120a and the integrated circuit package 130. At this point, the manufacturing process of the semiconductor package 100a shown in FIG. 23 is substantially done.

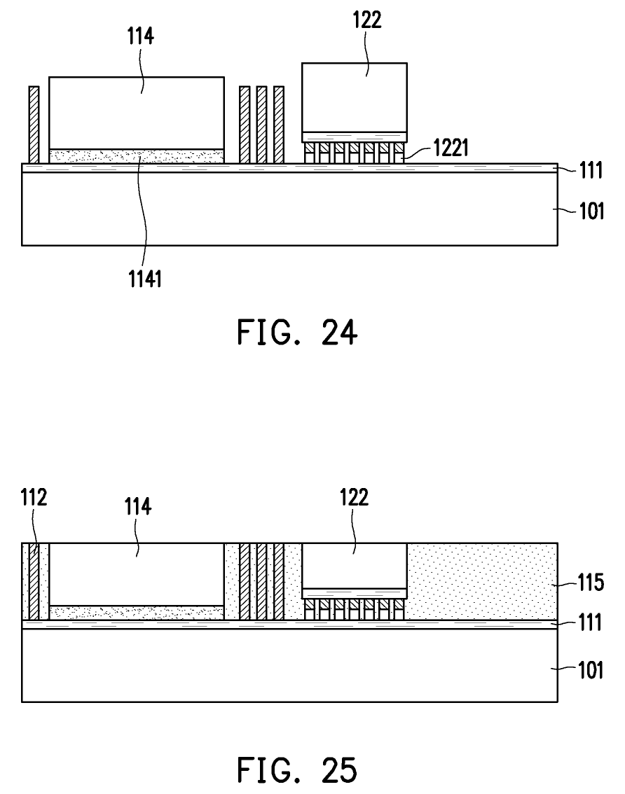

FIGS. 24-31 illustrate cross sectional views of intermediate stages in the manufacturing of a semiconductor package according to some exemplary embodiments of the present disclosure. It is noted that the manufacturing method of the semiconductor package shown in FIGS. 24-31 contains many features same as or similar to the embodiment disclosed earlier with FIGS. 1-10. For purpose of clarity and simplicity, detail description of same or similar features may be omitted, and the same or similar reference numbers denote the same or like components. In the embodiment shown in FIGS. 24-31, the dummy die, the electronic die, and the waveguide are embedded in the integrated interposer structure.

Referring to FIG. 24, in some embodiments, a plurality of through vias 112 and at least one embedded device is provided over the first carrier 101. The first carrier 101 may be a glass carrier substrate, a ceramic carrier substrate, a wafer (e.g., a silicon wafer), or the like. In the present embodiment, the first carrier 101 may be in a wafer form, such that multiple packages can be formed on the first carrier 101 simultaneously. In some embodiments, a release layer (not shown) may be formed over the first carrier 101. The release layer may be removed along with the first carrier 101 from the overlying structures that will be formed in subsequent steps. The release layer may be dispensed as a liquid and cured, may be a laminate film laminated onto the first carrier 101, or may be the like. The top surface of the release layer may be leveled and may have a high degree of planarity.

In accordance with some embodiments of the disclosure, before the through vias 112 and the embedded device are provided over the first carrier 101, the first redistribution structure 111 is formed. In some embodiments, the through vias 112 are formed over the first redistribution structure 111. The formation of the through vias may be the same or similar to the formation of the through vias in the previous embodiment. In some embodiments, multiple embedded devices are attached to the first redistribution structure 111. In the present embodiment, the embedded devices include the electronic die 122 of the optical engine module and at least one dummy die 114 for reducing warpage of the package. The embedded device may be placed on the first redistribution structure 111 using, e.g., a pick-and-place process. FIG. 24 illustrates one electronic die 122 and one dummy die 114, but in other embodiments, more than one electronic dies 122 and more than one dummy dies 114 may be attached.

In the embodiment, the electronic die 122 may be oriented with the conductive connectors 1221 facing toward the first carrier 101, as shown in FIG. 24. In some embodiments, the dummy die 114 may be attached to first redistribution structure 111 through a die attach film (DAF) 1141, which is an adhesive film. The dummy die 114 may be disposed at any suitable space and configured to adjust the amount of the insulation body that is subsequently formed, so as to reduce issues of thermal stress and warpage.

Referring to FIG. 25, in some embodiments, an insulation body 115 is provided (formed) over the first carrier 101. After formation, the insulation body 115 at least laterally encapsulates the plurality of through vias 112, the electronic die 113, and the dummy die 114. The insulation body 115 may be a molding compound, epoxy, or the like. The insulation body 115 may be applied by compression molding, transfer molding, lamination, or the like, and may be formed over the first carrier 101 such that the through vias 112 and/or the embedded device such as the interconnect device 113, the electronic die 113, and the dummy die 114 are buried or covered. The insulation body 115 may be applied in liquid or semi-liquid form and then subsequently cured.

Then, a planarization process is performed on the insulation body 115 to expose the through vias 112 and the back surfaces of the electronic die 113 and the dummy die 114. The back surfaces of the through vias 112, the electronic die 113, and the dummy die 114 may be coplanar with the upper surface of the insulation body 115 after the planarization process. The planarization process may be, for example, a chemical-mechanical polish (CMP), a grinding process, or the like. In some embodiments, the planarization may be omitted, for example, if the through vias 112 and/or the back surfaces of the electronic die 113 and the dummy die 114 are already exposed. Accordingly, from a structural point of view, the through vias 112 extend through the insulation body 115 after the planarization process.

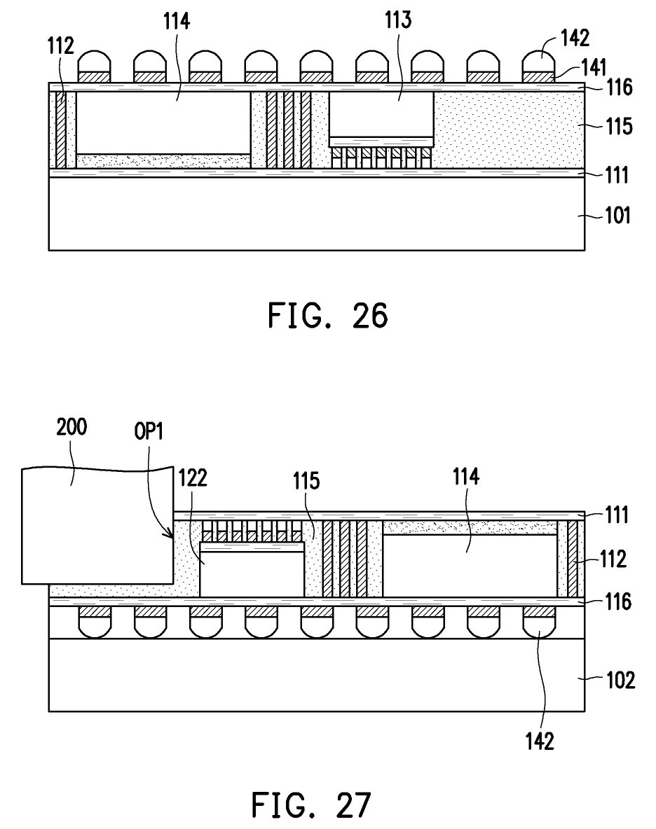

Referring to FIG. 26, the second redistribution structure 116 is formed. It should be appreciated that the second redistribution structure 116 may include any number of dielectric layers and metallization patterns. If more dielectric layers and metallization patterns are to be formed, steps and processes similar to those discussed above may be repeated. The metallization patterns may include conductive lines and conductive vias. The conductive vias may be formed during the formation of the metallization pattern by forming the seed layer and conductive material of the metallization pattern in the opening of the underlying dielectric layer. The conductive vias may therefore interconnect and electrically couple the various conductive lines.

In FIG. 26, a plurality of under-bump metallizations (UBMs) 141 and a plurality of conductive connectors 142 are formed for external connection to the second redistribution structure 116, in accordance with some embodiments. As a result, the UBMs 141 are electrically coupled to the through vias 112 and the electronic die 122. The conductive connectors 142 are then formed on the UBMs 141, in accordance with some embodiments. The conductive connectors 142 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 142 may include a conductive material such as solder, copper, aluminum, gold, nickel, silver, palladium, tin, the like, or a combination thereof. In some embodiments, the conductive connectors 142 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 142 include metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

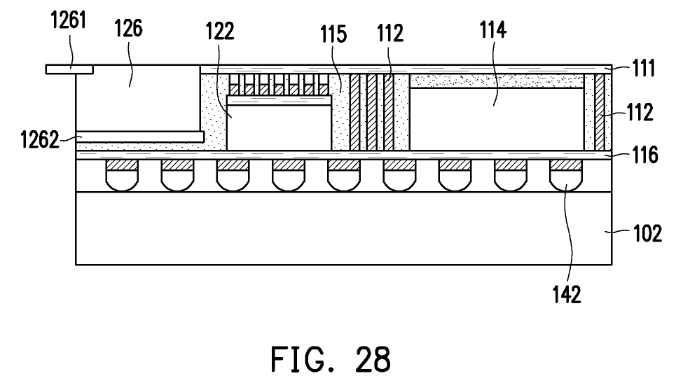

Then, referring to FIGS. 26 and 27, a de-bonding process is performed to detach (de-bond) the first carrier 101 from the conductive connectors 142. The structure is then flipped over and placed on a second carrier 102. Continuing with FIG. 27, in some embodiments, a concave OP1 is formed on an outer edge of the insulation body 115. The concave is formed right beside the electronic die 122. In some embodiments, the concave OP1 may be formed by trimming process by a trimming tool 200. In other embodiments, the concave OP1 may be formed by an etch process, or the like. Referring to FIG. 28, then, a waveguide 126 is disposed in the concave OP1. As such, the waveguide 126 is embedded in the integrated interconnect structure right beside the electronic device 122. In some embodiments, the waveguide 126 may be attached to a bottom surface of the concave OP1 through the adhesive film 1262 such as die attach film (DAF). In some embodiments, the waveguide 126 is an optical dielectric waveguide, but is not limited thereto. In some embodiments, a material of the waveguide 126 includes glass such as spin-on glass (SOG), silicon, silicon oxide, photoresist, epoxy, optical polymer such as polymethylmethacrylate, polyurethane or polyimide and other suitable optical dielectric material. In the present embodiment, the waveguide 126 is made of a glass die. In some embodiments, a top surface of the waveguide 126 is coplanar with a top surface of the first redistribution structure 111.

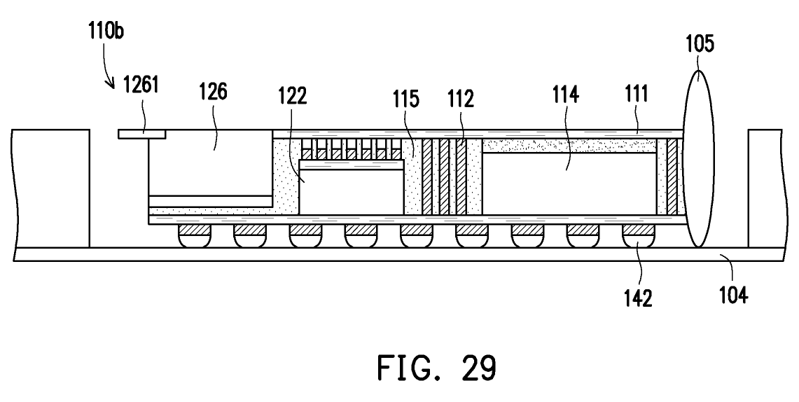

Then, referring to FIGS. 28 and 29 a de-bonding process is performed to detach (de-bond) the second carrier 102 from the conductive connectors 142. In accordance with some embodiments, the de-bonding includes projecting a light such as a laser light or an UV light on the release layer so that the release layer decomposes under the heat of the light and the second carrier 102 can be removed. The structure is then flipped over and placed on a tape 104. Then, a singulation process is performed by using sawing tool 105 to dice along scribe line regions. Accordingly, a plurality of integrated interconnect structures 110b (one is illustrated herein) separated from one another are formed. The integrated interconnect structures 110bin the present embodiment is embedded with the electronic die 122 and the waveguide of the optical engine module, and the dummy die 114.

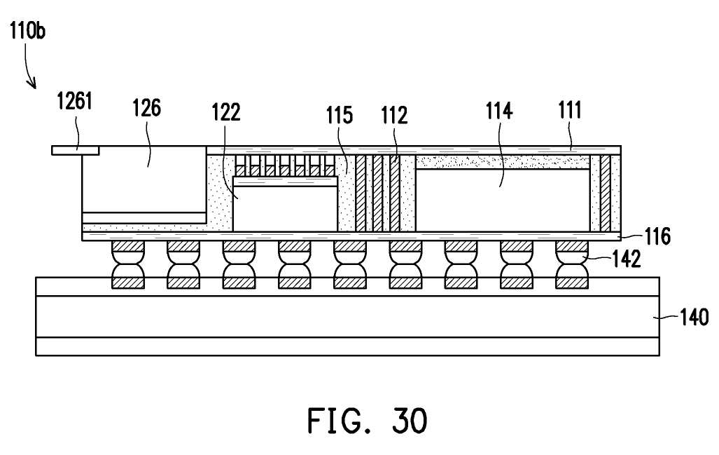

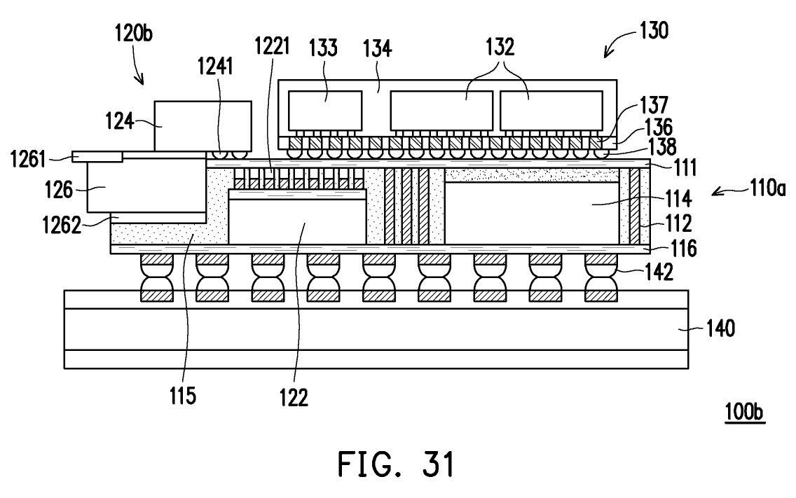

Then, referring to FIG. 30, the integrated interconnect structure 110b is flipped over, and bonded over a package substrate 140, in accordance with some embodiments. The integrated interconnect structure 110bis mounted to the package substrate 140 using a plurality of conductive connectors 142. The package substrate 140 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the package substrate 140 may be a SOI substrate. Generally, an SOI substrate includes a layer of a semiconductor material such as epitaxial silicon, germanium, silicon germanium, SOI, SGOI, or combinations thereof. The package substrate 400 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for package substrate 140. The package substrate 140 may include active and passive devices (not shown).

As one of ordinary skill in the art will recognize, a wide variety of devices such as transistors, capacitors, resistors, combinations of these, and the like may be used to generate the structural and functional requirements of the design for the semiconductor package. The devices may be formed using any suitable methods. In some embodiments, the conductive connectors 142 can be reflowed to attach the integrated interconnect structure 110b to the package substrate 140. The conductive connectors 142 are electrically and/or physically couple the package substrate 140, including metallization layers in the package substrate 140, to the integrated interconnect structure 110b. In some embodiments, an underfill (not shown) may be formed between the integrated interconnect structure 110b and the package substrate 140 and surrounding the conductive connectors 142. The underfill may be formed by a capillary flow process after the package substrate 140 is attached or may be formed by a suitable deposition method before the integrated interconnect structure 110b is attached.

Then, referring to FIG. 31, a photonic die 124 are bonded over the integrated interconnect structure 110b. In detail, the photonic die 124 stacked over and coupled to the electronic die 122 and the waveguide 126 embedded in the integrated interconnect structure 110b. In one embodiment, a coupling surface (e.g., the bottom surface) of the photonic die 124 includes a first portion electrically coupled to the electronic die 122 and a second portion optically coupled to the waveguide 126. In such embodiment, the first portion may include a plurality of conductive connectors 1241 for bonding to the first redistribution structure 111, and the second portion may be a substantially flat surface for optically coupled to the waveguide 126. The electronic die 122 and the waveguide 126 embedded in the integrated interconnect structure 110b, and the photonic die 124 bonded over the integrated interconnect structure 110b may be seen as an optical engine module 120b. In addition, the integrated circuit package 130 is bonded over the integrated interconnect structure 110b and electrically coupled to the optical engine module 120b. The electronic die 122 is connected to photonic die 124 and the integrated circuit package 130. In some embodiments, the optical engine module 120bis configured to receive optical signals from an optical device (e.g., an optical fiber 150 shown in FIG. 16) through pins 1261 of the waveguide 126. The photonic die 124 is optically coupled to the optical device 150 through the waveguide 126. In some embodiments, a heat dissipation device (not shown) such as a heat sink may be disposed on the photonic die 124 of the optical engine module 120 to facilitate heat dissipation.

In the embodiments of the present disclosure, the semiconductor package adopts the integrated interconnect structure interposed between the package substrate and the optical engine module/the integrated circuit package. Accordingly, the electrical routing between the optical engine module and the integrated circuit package is designed in the integrated interconnect structure, which can provide more space and fine line electrical interconnect, so as to improve bandwidth issues of the optical system having the semiconductor package. Moreover, with such configuration, the optical engine module and the integrated circuit package can be tested individually before being bonding to or embedded in the integrated interconnect structure, so the manufacturing cost can be reduced.

Based on the above discussions, it can be seen that the present disclosure offers various advantages. It is understood, however, that not all advantages are necessarily discussed herein, and other embodiments may offer different advantages, and that no particular advantage is required for all embodiments.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a semiconductor package includes a package substrate, an integrated interconnect structure, an optical engine module, and an integrated circuit package. The integrated interconnect structure is bonded over the package substrate and including an insulation body and a plurality of through vias extending through the insulation body. The optical engine module includes an electronic die, a photonic die, and a waveguide, wherein a portion of the optical engine module is embedded in the integrated interconnect structure. The integrated circuit package is bonded over the integrated interconnect structure and electrically coupled to the optical engine module. In one embodiment, the electronic die and the waveguide are embedded in the integrated interconnect structure, and the photonic die stacked over the electronic die and the waveguide. In one embodiment, the electronic die is connected to photonic die and the integrated circuit package. In one embodiment, the waveguide includes an optical dielectric waveguide. In one embodiment, the semiconductor package further includes an interconnect device embedded in the integrated interconnect structure, and the interconnect device is connected to the electronic die and the integrated circuit package. In one embodiment, the waveguide is embedded in the integrated interconnect structure. In one embodiment, the electronic die is bonded over the integrated interconnect structure and electrically coupled to the interconnect device, and the photonic die is stacked over the electronic die and the waveguide. In one embodiment, the semiconductor package further includes a dummy die embedded in the integrated interconnect structure. In one embodiment, the photonic die is optically coupled to an optical device through the waveguide. In one embodiment, the integrated circuit package includes a processing die and a memory die bonded over an interposer, and an encapsulating material laterally encapsulating the processing die and the memory die.

In accordance with some embodiments of the disclosure, a semiconductor package includes a package substrate, an integrated interconnect structure, an interconnect device, an optical engine module, and an integrated circuit package. The integrated interconnect structure includes an insulation body and a plurality of through vias extending through the insulation body. The interconnect device is embedded in the integrated interconnect structure. The optical engine module is bonded to the integrated interconnect structure and includes an electronic die, a photonic die and a waveguide. The integrated circuit package is bonded over the integrated interconnect structure and electrically coupled to the optical engine module through the interconnect device. In one embodiment, the waveguide is embedded in the integrated interconnect structure. In one embodiment, the electronic die is disposed over and connected to the interconnect device, and the photonic die is stacked over the electronic die and the waveguide. In one embodiment, the optical engine module is disposed over the integrated interconnect structure. In one embodiment, the waveguide and the electronic die are bonded to an upper surface of the integrated interconnect structure, and the photonic die is stacked over and coupled to the electronic die and the waveguide. In one embodiment, the integrated circuit package includes a processing die and a memory die bonded over an interposer, and an encapsulating material laterally encapsulating the processing die and the memory die.

In accordance with some embodiments of the disclosure, a manufacturing method of a semiconductor package includes the following steps. A plurality of through vias and an embedded device are provided over a carrier. An insulation body is provided over the carrier to form an integrated interconnect structure, wherein the insulation body at least laterally encapsulates the plurality of through vias and the embedded device. The carrier is removed. The integrated interconnect structure is bonded over a package substrate. A photonic die is bonded over the integrated interconnect structure, wherein the photonic die is coupled to the embedded device. An integrated circuit package is bonded over the integrated interconnect structure, wherein the integrated circuit package is coupled to the photonic die through the photonic die. In one embodiment, the manufacturing method of the semiconductor package further includes: forming a concave on an outer edge of the insulation body; and disposed a waveguide in the concave before the photonic die is bonded over the integrated interconnect structure. In one embodiment, the manufacturing method of the semiconductor package further includes: bonding an electronic die over the integrated interconnect structure, wherein the photonic die is stacked over the electronic die, and the embedded device comprises an interconnect device electrically coupled to the electronic die and the integrated circuit package. In one embodiment, the embedded device comprises an electronic die, wherein the photonic die is stacked over and electrically coupled to the electronic die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of a semiconductor package, comprising:
providing a plurality of through vias and an embedded device over a carrier;
providing an insulation body over the carrier to form an integrated interconnect structure, wherein the insulation body at least laterally encapsulates the plurality of through vias and the embedded device;
removing the carrier;
bonding the integrated interconnect structure over a package substrate;
bonding a photonic die over the integrated interconnect structure, wherein the photonic die is coupled to the embedded device; and
bonding an integrated circuit package over the integrated interconnect structure, wherein the integrated circuit package is coupled to the photonic die through the integrated interconnect structure.

2. The manufacturing method of the semiconductor package as claimed in claim 1, further comprising:
forming a concave on an outer edge of the insulation body; and
disposing a waveguide in the concave before the photonic die is bonded over the integrated interconnect structure.

3. The manufacturing method of the semiconductor package as claimed in claim 2, wherein the concave is formed by trimming process, or etching process.

4. The manufacturing method of the semiconductor package as claimed in claim 2, wherein the waveguide is attached to a bottom surface of the concave through an adhesive.

5. The manufacturing method of the semiconductor package as claimed in claim 1, further comprising:
bonding an electronic die over the integrated interconnect structure, wherein the photonic die is stacked over the electronic die.

6. The manufacturing method of the semiconductor package as claimed in claim 5, wherein the embedded device comprises an interconnect device electrically coupled to the electronic die and the integrated circuit package.

7. The manufacturing method of the semiconductor package as claimed in claim 1, wherein the embedded device comprises an electronic die embedded in the insulation body and electrically coupled to the photonic die and the integrated circuit package.

8. The manufacturing method of the semiconductor package as claimed in claim 1, wherein the embedded device comprises a dummy die electrically insulated from the through vias.

9. The manufacturing method of the semiconductor package as claimed in claim 1, further comprising:
bonding a waveguide and an electronic die to an upper surface of the integrated interconnect structure, wherein the photonic die is stacked over and coupled to the electronic die and the waveguide.

10. The manufacturing method of the semiconductor package as claimed in claim 1, further comprising:
embedding a waveguide in the insulation body; and
mounting an optical fiber to a side of the insulation body, wherein the optical fiber is optically coupled to the waveguide.

11. A manufacturing method of a semiconductor package, comprising:
providing an integrated interconnect structure comprising an insulation body and a plurality of through vias extending through the insulation body;
bonding the integrated interconnect structure over a package substrate;
bonding an optical engine module to the integrated interconnect structure, wherein the optical engine module comprises an electronic die, a photonic die, and a waveguide, wherein a portion of the optical engine module is embedded in the integrated interconnect structure; and
bonding an integrated circuit package over the integrated interconnect structure, wherein the integrated circuit package is coupled to the optical engine module.

12. The manufacturing method of the semiconductor package as claimed in claim 11, wherein bonding the optical engine module to the integrated interconnect structure further comprises:
forming a concave on an outer edge of the insulation body;
disposing a waveguide in the concave;
bonding the electronic die over the integrated interconnect structure; and
bonding the photonic die over the electronic die and the waveguide.

13. The manufacturing method of the semiconductor package as claimed in claim 12, further comprising:
mounting an optical fiber to a side of the insulation body, wherein the optical fiber is optically coupled to the waveguide.

14. The manufacturing method of the semiconductor package as claimed in claim 11, wherein providing the integrated interconnect structure comprising:
providing a plurality of through vias over a carrier;
providing an embedded device over a carrier;
providing an insulation body over the carrier, wherein the insulation body at least laterally encapsulating the plurality of through vias and the embedded device; and
removing the carrier.

15. The manufacturing method of the semiconductor package as claimed in claim 11, wherein the electronic die is embedded in the insulation body, and bonding the optical engine module to the integrated interconnect structure further comprises:
forming a concave on an outer edge of the insulation body;
disposing a waveguide in the concave;
bonding the photonic die over the electronic die and the waveguide.

16. A manufacturing method of a semiconductor package, comprising:
providing an integrated interconnect structure comprising an insulation body, a plurality of through vias extending through the insulation body, and an interconnect device embedded in the insulation body;
bonding the integrated interconnect structure over a package substrate;
bonding an optical engine module to the integrated interconnect structure, wherein the optical engine module comprises an electronic die, a photonic die and a waveguide; and
bonding an integrated circuit package over the integrated interconnect structure, wherein the integrated circuit package is electrically coupled to the optical engine module through the interconnect device.

17. The manufacturing method of the semiconductor package as claimed in claim 16, wherein bonding the optical engine module to the integrated interconnect structure comprises:
forming a concave on an outer edge of the integrated interconnect structure;
bonding the waveguide on a bottom surface of the concave;
bonding the electronic die over the interconnect device; and
stacking the photonic die over the electronic die and the waveguide.

18. The manufacturing method of the semiconductor package as claimed in claim 16, wherein the interconnect device is electrically coupled to the optical engine module and the integrated circuit package.

19. The manufacturing method of the semiconductor package as claimed in claim 16, wherein the integrated circuit package comprising a processing die and a memory die bonded over an interposer, an encapsulating material at least laterally encapsulates the processing die and the memory die.

20. The manufacturing method of the semiconductor package as claimed in claim 16, wherein bonding the optical engine module to the integrated interconnect structure comprises:
bonding the waveguide and the electronic die over an upper surface of the integrated interconnect structure; and
bonding the photonic die over and coupled to the electronic die and the waveguide.
